(19) United States
(12) Patent Application Publication
(10) Pub. No.: US 2026/0344783 A1
(43) Pub. Date: Nov. 5, 2026

(54) POWER CONTROL UNIT

(71) Applicant: NICOVENTURES TRADING LIMITED, London (GB)

(72) Inventor: Zhihuang XIAO, London (GB)

(21) Appl. No.: 19/124,436

(22) PCT Filed: Oct. 26, 2023
(86) PCT No.: PCT/GB2023/052801

§ 371 Date: Apr. 25, 2025

(30) Foreign Application Priority Data
Oct. 26, 2022 (GB) 2215852.1

(51) Int. Cl. A24F 40/50; H02M 1/08; H02M 3/158; H05B 1/02; H05B 3/02

(52) U.S. Cl. CPC A24F 40/50; H02M 1/08; H02M 3/158; H05B 1/0202; H05B 3/02

(57) ABSTRACT

A power control unit is disclosed, comprising at least one power supply terminal for connection to an electrical power supply, at least one load terminal for connection to an electrical load, an electrical current path configured to connect the at least one power supply terminal to the at least one load terminal, and a plurality of switches connected in series along the electrical current path. The power control unit comprises control logic configured to independently switch each of the plurality of switches between an open-circuit state and a closed-circuit state, and to supply electrical current to the load terminal via the electrical current path. The control logic is further configured to determine if at least a first switch of the plurality of switches is in an adverse operating state, and to modify an aspect of the provision of electrical current to the load terminal via the electrical current path on the basis of said determination. The power control unit may be included in an aerosol provision device, which may itself form part of an aerosol provision system. A method of operating a power control unit is also disclosed.

### FIELD

The present disclosure relates to computing devices, and in particular, computing devices comprising application specific integrated circuits (ASICs).

### BACKGROUND

In many contexts, electrical devices comprise power supply units (which may be referred to as power controllers or power control units) which regulate a supply of electrical power from an electrical power source to an electrical load. In such a power supply unit, which is often referred to in the art as a ‘switched mode power supply’ (SMPS), at least one switching element is disposed on a direct or indirect current path between a power source (such as, for example, a mains electrical outlet, optionally stepped up or down in voltage and/or current by a transformer module; or a battery or capacitor unit). Each of one or more switching elements in such a power supply unit is typically provided with switching control logic operable to open and close the at least one switching element to regulate a supply of electrical current between the power source and one or more electrical loads. In some power supply units of this type, switching elements are implemented as relays or solid-state switches (for example field-effect transistors), such that there is a high degree of electrical isolation (i.e. impedance) between a first circuit path comprising control logic providing control signals to modify the switch state of each switch, and a second circuit path (typically carrying signals at higher power than the first circuit path) which is switched between an open and closed circuit state by the one or more switches under control of the switching control logic.

In a typical power supply unit, the switching control logic may typically comprise a microcontroller configured to provide switch driving signals to actuates one or more switch elements to complete an electrical path between the power source and an electrical load. The control logic may be connected to one or more input terminals, configured to be connected to external circuitry which is configured to provide trigger signals to the power supply unit, and the control logic is configured to actuate the switch(es) when a certain trigger condition is met, such as the receiving of a predefined input signal from, for example, an external computing device, a sensor, and/or manual input element (e.g. a button or switch). Alternatively, or in addition, switching may be controlled by the control logic of the controller element, without external input, according to, for example, a switching scheme implemented in firmware/software running on processing hardware of the controller element.

Failure of electrical components represents a particular safety concern in the context of power supply units. In particular, failure of electrical components on the electrical path between a power source and a load may lead to overheating of components, and risk of elevated temperatures potentially causing damage to the device or system in which the power supply module is implemented, and/or injury to a user. This may be considered of particular concern in devices comprising one or more heaters, as is often the case in the context of aerosol provision systems. Where an electrical load configured to receive power under control of a power supply unit comprises a heater, a failure of the power supply unit to regulate the supply of power to the heater (particularly if this is due to a closed-circuit failure between a power source and the heater), may result in overheating of the heater (and/or the power supply unit) with associated risks of device damage (e.g. fire) and/or user injury. Thus, mitigating risk associated with switch malfunction and/or failure in power supply unit for electrical devices is of interest. The inventor has recognised that it may be advantageous to provide control functionality for a power supply unit (e.g. a SMPS) which mitigates against such risk. Various approaches are described herein which seek to help address or mitigate at least some of the issues discussed above.

### SUMMARY

According to a first aspect of the present disclosure, there is provided a power control unit, comprising: at least one power supply terminal for connection to an electrical power supply; at least one load terminal for connection to an electrical load; an electrical current path configured to connect the at least one power supply terminal to the at least one load terminal; and a plurality of switches connected in series along the electrical current path, wherein the power control unit comprises control logic configured to independently switch each of the plurality of switches between an open-circuit state and a closed-circuit state; wherein the control logic is configured to supply electrical current to the load terminal via the electrical current path; and wherein the control logic is further configured to determine if at least a first switch of the plurality of switches is in an adverse operating state, and to modify an aspect of the provision of electrical current to the load terminal via the electrical current path on the basis of said determination.

According to a second aspect of the present disclosure, there is provided a method of operating a power control unit to control a supply of power on an electrical current path configured to connect at least one power supply terminal for connection to an electrical power supply to at least one load terminal for connection to an electrical load, via a plurality of switches connected in series along the electrical current path; wherein the method comprises operating control logic comprised in the power control unit, the control logic being configured to supply electrical current to the load terminal via the electrical current path, to cause the control logic to independently switch each of the plurality of switches between an open-circuit state and a closed-circuit state; wherein the method comprises, at the control logic: determining if at least a first switch of the plurality of switches is in an adverse operating state, and modifying an aspect of the provision of electrical current to the load terminal via the electrical current path on the basis of said determination.

According to a third aspect of the present disclosure, there is provided a computer program product comprising instructions to cause a power control unit configured according to the first aspect to execute the steps of the method according to the second aspect.

According to a fourth aspect of the present disclosure, there is provided a computer-readable medium having stored thereon a computer program product according to the third aspect.

It will be appreciated that features and aspects of the invention described above in relation to the first and other aspects of the invention are equally applicable to, and may be combined with, embodiments of the invention according to other aspects of the invention as appropriate, and not just in the specific combinations described above.

### BRIEF DESCRIPTION OF THE DRAWINGS

Embodiments of the disclosure will now be described, by way of example only, with reference to the accompanying drawings, in which:

FIG. 1 is a schematic diagram of an aerosol provision system in which a power supply unit according to embodiments of the present disclosure may be implemented.

FIG. 2 is a schematic diagram of a power supply unit comprising a single solid-state switch.

FIG. 3 is a schematic diagram of a power supply unit according to embodiments of the present disclosure.

FIG. 4 is a flowchart detailing aspects of operation of a power supply unit according to embodiments of the present disclosure.

### DETAILED DESCRIPTION

Aspects and features of certain examples and embodiments are discussed/described herein. Some aspects and features of certain examples and embodiments may be implemented conventionally and these are not discussed/described in detail in the interests of brevity. It will thus be appreciated that aspects and features of apparatus and methods discussed herein which are not described in detail may be implemented in accordance with any conventional techniques for implementing such aspects and features.

The present disclosure relates to power control units (which may be interchangeably referred to herein as switched-mode power supplied, power controllers, and power control modules) for electrical/electronic devices. The term ‘electrical/electronic device’ herein encompasses any system or device in which it switching of power between an electrical source and a load is required, and thus may include handheld consumer electronic devices (e.g. digital cameras, digital video cameras, GPS units, telephones, watches, digital music players), household appliances (e.g. washing machines, dryers, fridges, freezers, dishwashers, smart speakers, microwaves, toasters, coffee makers, or blenders), vehicles (e.g. cars, aircraft, spacecraft, satellites, drones/UAVs, or trains), and computer peripherals and/or modules in computer systems (e.g. motherboards, hard drives, sound or graphics cards, wireless telecommunications controllers, or network switches), or any other electrical/electronic device known to the skilled person. Herein, aerosol provision systems are presented as an exemplary use context in which embodiments of power control units according to the present disclosure may be implemented, for the sake of providing a concrete example of an application. However, it will be understood that this operating context is merely exemplary, and the subject matter of the present disclosure may be applied in respect of other use cases, particularly in electrical/electronic devices in which enhanced reliability/safety of electrical switching is desirable. Thus whilst embodiments of a power control unit as described herein may be referred to as a power control unit configured for use in an electronic aerosol provision system, the same embodiments may be applied for use in controlling a supply of electrical power to one or more electrical loads in the context of any other kind of electronic/electrical/electro-mechanical device or system, and the power control units described herein may be referred to as a power control units configured for use in an electrical/electronic system or device, or configured for use in a consumer electrical device.

Aerosol provision systems are an example of a type of handheld consumer electrical device in which a reusable part/power control unit (or ‘aerosol provision device’) according to the present disclosure may be implemented. Aerosol provision systems, may comprise so-called ‘e-cigarettes’ or ‘electronic cigarettes’ configured to aerosolise a supply of aerosol generating material in liquid or gel form, or may comprise so-called ‘heat-not-burn’ or ‘tobacco heating’ devices configured to aerosolise a supply of solid aerosol generating material (e.g. tobacco). Aerosol provision system may comprise a modular assembly including both a reusable part (i.e. aerosol provision device), which may be referred to herein as a control unit, and a replaceable (disposable) part which may be referred to herein as a cartridge, cartomiser, pod unit, or consumable. In such embodiments, the replaceable part will typically comprise a supply aerosol generating material and an aerosol generator (e.g. a heater), and the reusable part will comprise a power supply (e.g. rechargeable power source) and a controller configured to provide control logic to support functions of the aerosol provision system. It will be appreciated these different parts may comprise further elements depending on the required functionality, as described further herein, and/or known to the skilled person. Replaceable parts of the aerosol provision system may be electrically and mechanically coupled to a reusable part for use, for example using a screw thread, bayonet, or magnetic coupling with appropriately arranged electrical contacts (in instances where an aerosol generator and/or other electrical components are comprised in the replaceable part). When a supply of aerosol generating material in a replaceable part is exhausted, or the user wishes to switch to a different replaceable part having a different aerosol generating material, a replaceable part may be removed from the reusable part, and a different/new replaceable part attached in its place. Devices conforming to this type of two-part modular configuration may generally be referred to as two-part devices. Alternatively, the components described above as distributed between a separable reusable part and a replaceable part may be integrated into a single housing, such that a part of the device containing aerosol generating material (e.g. in a reservoir) is not designed to be replaced by a user. Such a device, which may be referred to as a single-part or uni-part aerosol provision system or device, may be configured to allow a user to refill a reservoir or container of aerosol generating material, or may not be designed to allow refill by a user. Such a device may be referred to as a ‘disposable’ aerosol delivery device/system, and may be manufactured to comprise a battery and a supply of aerosol generating material which are sized (in terms of capacity) to support a certain number of puffs before the device is no longer able to generate aerosol for a user (e.g. because the supply of electrical power and/or aerosol generating material are exhausted). When this point is reached, the device may be configured to be disposed of or recycled. Disposable aerosol provision systems, which are designed to be disposed of after a target number of puffs, may typically be designed to be relatively simple, with low per-unit production costs compared to reusable aerosol provision systems, and thus the inventor has recognised that the use of a relatively small and simple high-power-density power control unit, having integrated safety features, may be particularly advantageous in this context, particularly, though not exclusively, if the power control logic and switches of the power control unit are comprised in an ASIC package as described in embodiments of the present disclosure.

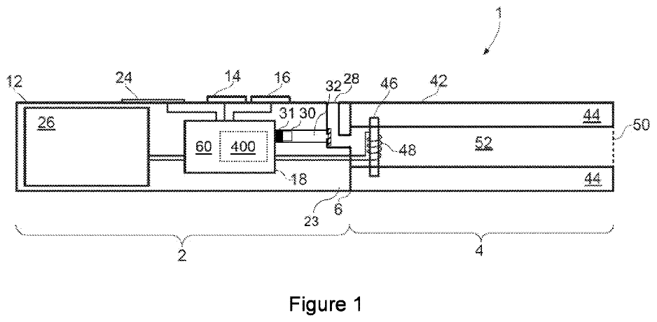

FIG. 1 is a cross-sectional view through an example aerosol provision system, which is provided as an exemplary and non-limiting use context for a power control unit configured in accordance with certain embodiments of the disclosure. The aerosol provision system 1 shown in FIG. 1 comprises two main components, namely a reusable part 2 and a replaceable/disposable cartridge or consumable part 4 (the words cartridge and consumable may be used interchangeably herein). In normal use the reusable part 2 and the consumable part 4 are releasably coupled together at an interface 6. When the consumable part is exhausted or the user simply wishes to switch to a different consumable part, the consumable part may be removed from the reusable part and a replacement cartridge part attached to the reusable part in its place. The interface 6 provides a structural, electrical and airflow path connection between the two parts and may be established in accordance with conventional techniques, for example based around a screw thread, magnetic or bayonet fixing with appropriately arranged electrical contacts and openings for establishing the electrical connection and airflow path between the two parts as appropriate. The specific manner by which the replaceable part 4 mechanically mounts to the reusable part 2 is not significant to the principles described herein. As known to the skilled person, in some examples, an aerosol generator may be provided in the reusable part 2 rather than in the replaceable part 4, or the transfer of electrical power from the reusable part 2 to the replaceable part 4 may be wireless (e.g. based on electromagnetic induction), so that an electrical connection between the reusable part and the replaceable part 4 is not needed.

The cartridge/consumable/replaceable part 4 may in accordance with certain embodiments of the disclosure be broadly conventional, designed and constructed according to approaches known to the skilled person. In FIG. 1, the cartridge part 4 comprises a cartridge housing 42 formed of a plastics material. The cartridge housing 42 supports other components of the cartridge part and provides the mechanical interface 6 with the reusable part 2. Within the cartridge housing 42 is a reservoir 44 that contains aerosol generating material. Aerosol generating material is a material that is capable of generating aerosol, for example when heated, irradiated or energized in any other way. Aerosol generating material may, for example, be in the form of a solid, liquid or gel which may or may not contain an active substance and/or flavourants. In some embodiments, the aerosol-generating material may comprise plant material such as tobacco. In some embodiments, the aerosol-generating material may comprise an “amorphous solid”, which may alternatively be referred to as a “monolithic solid” (i.e. non-fibrous). In some embodiments, the amorphous solid may be a dried gel. The amorphous solid is a solid material that may retain some fluid, such as liquid, within it. In some embodiments, the aerosol generating material may for example comprise from about 50 wt %, 60 wt % or 70 wt % of amorphous solid, to about 90 wt %, 95 wt % or 100 wt % of amorphous solid. The aerosol generating material may comprise one or more active substances and/or flavours, one or more aerosol-former materials, and optionally one or more other functional material. An aerosol-former material may comprise one or more constituents capable of forming an aerosol, as known to the skilled person. One or more active constituents/substances comprised in the consumable part may comprise one or more physiologically and/or olfactory active constituents which are included in the aerosolisable material in order to achieve a physiological and/or olfactory response in the user. In some embodiments, the active constituent is a physiologically active constituent and may be selected from nicotine, nicotine salts (e.g. nicotine ditartrate/nicotine bitartrate), nicotine-free tobacco substitutes, other alkaloids such as caffeine, cannabinoids, or mixtures thereof.

In the example shown schematically in FIG. 1, a reservoir 44 is provided configured to store a supply of liquid aerosol generating material. In this example, the liquid reservoir 44 has an annular shape with an outer wall defined by the cartridge housing 42 and an inner wall that defines an airflow path 52 through the cartridge part 4. The reservoir 44 is closed at each end with end walls to contain the aerosol generating material. The reservoir 44 may be formed in accordance with conventional techniques, for example it may comprise a plastics material and be integrally moulded with the cartridge housing 42. This configuration is exemplary, and any aerosol generating material storage and airflow configuration known to the skilled person may alternatively be used.

The cartridge (which may also be referred to herein as a consumable part) further comprises an aerosol generator 48 located towards an end of the reservoir 44 opposite to the mouthpiece outlet 50. An aerosol generator is an apparatus configured to cause aerosol to be generated from the aerosol-generating material. In some embodiments, the aerosol generator is a heater configured to subject the aerosol-generating material to heat energy, so as to release one or more volatile materials from the aerosol-generating material to form an aerosol. In some embodiments, the aerosol generator is configured to cause an aerosol to be generated from the aerosol-generating material without heating. For example, the aerosol generator may be configured to subject the aerosol-generating material to one or more of vibration, increased pressure, or electrostatic energy.

It will be appreciated that in a two-part device such as shown in FIG. 1, the aerosol generator may be in either of the reusable part 2 or the cartridge part 4. For example, in some embodiments, the aerosol generator 48 (e.g. a heater) may be comprised in the reusable part 2, and is brought into proximity with a portion of aerosol generating material in the cartridge 4 when the cartridge is engaged with the reusable part 2. In such embodiments, the cartridge may comprise a portion of aerosol generating material, and an aerosol generator 48 comprising a heater is at least partially inserted into or at least partially surrounds the portion of aerosol generating material as the cartridge 4 is engaged with the reusable part 2. In the example of FIG. 1, a wick 46 in contact with a heater 48 extends transversely across the cartridge airflow path 52 with its ends extending into the reservoir 44 of a liquid aerosol generating material through openings in the inner wall of the reservoir 44. The openings in the inner wall of the reservoir are sized to broadly match the dimensions of the wick 46 to provide a reasonable seal against leakage from the liquid reservoir into the cartridge airflow path without unduly compressing the wick, which may be detrimental to its fluid transfer performance.

In the example of FIG. 1, the wick 46 and heater 48 are arranged in the cartridge airflow path 52 such that a region of the cartridge airflow path 52 around the wick 46 and heater 48 in effect defines a vaporisation region for the cartridge part 4. Aerosol generating material in the reservoir 44 infiltrates the wick 46 through the ends of the wick extending into the reservoir 44 and is drawn along the wick by surface tension/capillary action (i.e. wicking). The heater 48 in this example comprises an electrically resistive wire coiled around the wick 46. In the example of FIG. 1, the heater 48 comprises a nickel chrome alloy (Cr20Ni80) wire and the wick 46 comprises a cotton bundle, but it will be appreciated the specific aerosol generator configuration is not significant to the principles described herein. In use electrical power may be supplied from the power source/battery 26 to the heater 48 by a controller 60, to vaporise an amount of aerosol generating material (aerosol generating material) drawn to the vicinity of the heater 48 by the wick 46. Vaporised aerosol generating material may then become entrained in air drawn along the cartridge airflow path from the vaporisation region towards the mouthpiece outlet 50 for user inhalation. Although the aerosol generator 48 illustrated in FIG. 1 comprises a resistive wire coiled around a wick 46, this is not essential and it will be appreciate that other forms of aerosol generator may be used, such as a ceramic heater, flat plate heater, an inductive drive unit (e.g. a drive coil) providing a magnetic field to cause heating of a susceptor element in contact with aerosol generating material, etc.

The rate at which aerosol generating material is vaporised by the aerosol generator (e.g. heater) 48 will typically depend on the amount (level) of power supplied to the heater 48. Thus electrical power can be applied to the heater to selectively generate aerosol from the aerosol generating material in the cartridge part 4, and furthermore, the rate of aerosol generation can be changed by changing the amount of power supplied to the heater 48, for example through pulse width and/or frequency modulation techniques implemented using a power control unit/module 400 configured according to embodiments of the present disclosure.

The reusable part 2 may comprise an outer housing 12 having with an opening that defines an air inlet 28 for the aerosol provision system. It further comprises a power source 26 (for example a battery) for providing operating power for the electronic cigarette, and control circuitry/controller 60 for controlling and monitoring operations of the electronic cigarette The reusable part 2 may optionally comprise one or more user input and mechanisms, such as a first user input button 14, a second user input button 16, and a visual feedback components such as a visual display 24.

The power source 26 in the example of FIG. 1 may comprise a rechargeable battery and may be of a conventional type, for example of the kind normally used in electronic cigarettes and other applications requiring provision of relatively high currents over relatively short periods. The power source 26 may be recharged through a charging connector in the reusable part housing 12, for example a USB connector. In other instances, for example in disposable aerosol provision systems, the power source 26 may not be configured to be rechargeable by a user, and a charging connector may not be provided. The power source 26 may be supplied fully charged, and is configured to be disposed of with all or part of the aerosol provision system 1 when it has been fully discharged (i.e. when it no longer provides sufficient power to enable generation of aerosol).

One or more user input mechanisms (e.g. buttons 14, 16) may be provided, which in the example of FIG. 1 are conventional mechanical buttons, for example comprising a spring mounted component which may be pressed by a user to establish an electrical contact. In this regard, the input buttons may be considered input devices for detecting user input and the specific manner in which the buttons are implemented is not significant. The buttons may be assigned to functions such as switching the aerosol provision system 1 on and off, and adjusting user settings such as a power to be supplied from the power source 26 to an aerosol generator 48. A user input mechanism, where included, may directly or indirectly provide a trigger to a power control unit 400 as described herein, to indicate one or more switches of the power control unit should be closed to allow an aerosol generation current (e.g. heating current) to pass from the power source to the electrical load (e.g. aerosol generator 48). However, the inclusion of user input buttons is optional, and in some embodiments buttons may not be included, or a different form of user input mechanism may be provided.

A visual feedback mechanism/display unit 24 may be provided to supply visual indications of various characteristics associated with the aerosol provision system 1, for example power setting information, remaining battery power, an amount of usage (e.g. in puffs), a remaining supply of aerosol generating material, and so forth. The display unit 24 may be implemented in various ways. In the example of FIG. 1 the display unit 24 may comprise a conventional pixilated LCD screen that may be driven by the controller 60 to display operating information in accordance with conventional techniques. In other implementations the display unit 24 may comprise one or more discrete indicators, for example LEDs (not shown), that are arranged to display operating information, for example through predefined colours and/or illumination patterns. In some examples, the display unit 24 may comprise a touchscreen display providing user input functionality which may alternatively or additionally be provided by one or more buttons as described further herein. More generally, the manner in which a display unit 24 is provided and information is displayed to a user using such a display unit 24 is not significant to the principles described herein. For example some aerosol provision systems may not include a display unit 24, and may optionally include other means for providing a user with information relating to operating characteristics of the aerosol provision system, for example using audio or haptic feedback elements (not shown), or may not include any means for providing a user with information relating to operating characteristics of the aerosol provision system.

A controller 60 may be suitably configured/programmed to control the operation of the aerosol provision system to provide functionality in accordance with embodiments of the disclosure as described further herein, as well as for providing conventional operating functions of the aerosol provision systemin line with the established techniques for controlling such devices. The controller (i.e. processor circuitry) 60 may be considered to logically comprise various functional units/modules associated with different aspects of the operation of the aerosol provision system 1. Each of the functional units described herein may be implemented in hardware, for example as a functional unit of an application specific integrated circuit (ASIC). In the example of FIG. 1, the controller 60 may comprise a functional unit configured as a power supply unit 400 as described further herein, for controlling the supply of power from the power source 26 to the aerosol generator 48 in response to user input, and further comprise a functional unit which is user-programmable to establishing configuration settings (e.g. user-defined power settings) in response to user input, as well as other functional units/circuitry supporting other functionality of the aerosol provision system in accordance with principles described herein and/or conventional operating aspects of electronic cigarettes, such as user feedback functions, charging functions, and wireless and/or wired communication functions. It will be appreciated the functionality of the controller 60 can be provided in various different ways, for example using one or more suitably programmed programmable computer(s) and/or one or more suitably configured application-specific integrated circuit(s)/circuitry/chip(s)/chipset(s) configured to provide the desired functionality. For example, the controller 60 may comprise a first ASIC package or MCU chip providing control logic supporting a first set of device functions, with electrical interconnects to a second ASIC package comprising a power control unit 400 as described herein, configured to switch on and off a supply of electrical power from the battery 26 to the aerosol generator 48; or the controller 60 may comprise an ASIC package supporting all electrical/electronic control functions of the device, and comprising a power control sub-unit 400 (e.g. a functional unit) defined on the same die/chip/wafer, the power control unit 400 being specifically configured to switch on and off a supply of electrical power from the battery 26 to the aerosol generator 48. The controller 60 may comprise an application specific integrated circuit (ASIC) or microcontroller, comprising hardware and/or firmware/software control logic for controlling functions of the aerosol provision system. The microcontroller or ASIC may include a CPU or micro-processor. Software/firmware associated with the operation of the controller 60 may be stored in non-volatile memory, such as ROM, which can be integrated into the controller 60 itself, or provided as a separate component. A CPU or MCU comprised in the controller 60 may access the ROM to load and execute individual software programs as and when required.

Reusable part 2 comprises an activation element which directly or indirectly allows a user to provide input to the controller 60 and/or power control unit 400 to indicate a demand for aerosol. The activation element may comprise an airflow sensor 30 which is electrically connected to the controller 60. In most embodiments, the airflow sensor 30 comprises a so-called “puff sensor”, in that the airflow sensor 30 is used to detect when a user is puffing on the device by detecting airflow (e.g. a change in pressure, airflow speed, or acoustic signals associated with a puff). In some embodiments, the airflow sensor comprises a switch in an electrical path providing electrical power from the power source 26 to the aerosol generator 48. In such embodiments, the airflow sensor 30 may comprise a pressure sensor configured to close the switch when subjected to an particular range of pressures, enabling current to flow from the power source 26 to the aerosol generator 48 once the pressure in the vicinity of the airflow sensor 30 drops below a threshold value. The threshold value can be set to a value determined by experimentation to correspond to a characteristic value or range of values associated with the initiation of a user puff. In other embodiments, the airflow sensor 30 is connected to the controller 60 and/or power control unit 400, and the controller/power control unit distributes electrical power from the power source 26 to the aerosol generator 48 in dependence of a signal received from the airflow sensor 30.

In the example shown in FIG. 1, the airflow sensor 30 is mounted to a printed circuit board 31, but this is not essential, and as described further herein, the airflow sensor may be comprised in a power control unit 400 (e.g. implemented as an ASIC package). The airflow sensor 30 may comprise any sensor which is configured to determine a characteristic of airflow in an airflow path 51 disposed between air inlet 28 and mouthpiece opening 50, for example a pressure sensor or transducer (for example a membrane or solid-state pressure sensor, such as a MEMS pressure sensor), a combined temperature and pressure sensor, or a microphone (for example an electret-type microphone), which is sensitive to changes in air pressure, including acoustical signals. The airflow sensor may typically be situated within a sensor cavity/chamber 32, which, where present, comprises the interior space defined by one or more chamber walls 34 in which an airflow sensor 30 can be fully or partially situated. The airflow sensor 30 may be mounted to a printed circuit board (PCB) 31 or comprised in an ASIC package, which comprises one of the chamber walls 34 of a sensor housing comprising the sensor chamber/cavity 32. A deformable membrane can be disposed across an opening communicating between the sensor cavity 32 containing the sensor 30, and a portion of the airflow path disposed between air inlet 28 and mouthpiece opening 50. The deformable membrane covers the opening, and is attached to one or more of the chamber walls according to approaches described further herein. It will be appreciated an airflow sensor 30, where present, may not be positioned in a dedicated sensor cavity 32, and may be situated anywhere in the airflow path, according to any suitable approach known to the skilled person. As described herein, in embodiments where the controller 60 comprises or constitutes a power control unit 400, the airflow sensor 30 may be integrated into the controller 60.

Whilst the aerosol provision system of FIG. 1 has been shown as comprising a replaceable part 4 and a reusable part 2, it will be appreciated this is only exemplary, and in other instances, such an aerosol provision system may comprise a single-part device, which may be designed to be disposable after an initial supply of electrical power and/or aerosol generating material, supplied at manufacture, have been exhausted. Thus an aerosol provision system 1 as shown in FIG. 1 or otherwise described herein may not comprise a connection interface 6, but rather the components comprised in the device (e.g. as shown in the example device of FIG. 1) may be housed within a single housing, and the aerosol provision system may be referred to as a ‘disposable’ aerosol provision system, or ‘single-part’ aerosol provision system.

The aerosol provision system may 1 comprise communication circuitry configured to enable a connection to be established with one or more further electronic devices (for example, a smartphone, personal computer, external server, storage/charging case, and/or a refill/charging dock) to enable data transfer between the aerosol provision system 1 and further electronic device(s). In some embodiments, the communication circuitry is integrated into controller 60, and in other embodiments it is implemented separately (comprising, for example, separate application-specific integrated circuit(s)/circuitry/chip(s)/chipset(s)). For example, the communication circuitry may comprise a separate module to the controller 60 which, while connected to controller 60, provides dedicated data transfer functionality for the aerosol provision system. In some embodiments, the communication circuitry is configured to support communication between the aerosol provision system 1 and one or more further electronic devices over a wireless interface. The communication circuitry may be configured to support wireless communications between the aerosol provision system 1 and other electronic devices such as a case, a dock, a computing device such as a smartphone or PC, a base station supporting cellular communications, a relay node providing an onward connection to a base station, a wearable device, or any other portable or fixed device which supports wireless communications.

Wireless communications between the aerosol provision system 1 and a further electronic device may be configured according to known data transfer protocols such as Bluetooth, ZigBee, WiFi, Wifi Direct, GSM, 2G, 3G, 4G, 5G, LTE, NFC, RFID. More generally, it will be appreciated that any wireless network protocol can in principle be used to support wireless communication between the aerosol provision system 1 and further electronic devices. In some embodiments, the communication circuitry is configured to support communication between the aerosol provision system 1 and one or more further electronic devices over a wired interface. This may be instead of or in addition to the configuration for wireless communications set out above. The communication circuitry may comprise any suitable interface for wired data connection, such as USB-C, micro-USB or Thunderbolt interfaces. More generally, it will be appreciated the communication circuitry may comprise any wired communication interface which enables the transfer of data, according to, for example, a packet data transfer protocol, and may comprise pin or contact pad arrangements configured to engage cooperating pins or contact pads on a dock, case, cable, or other external device which can be connected to the aerosol provision system 1.

As set out further herein, the description of an aerosol provision system 1 in accordance with FIG. 1 is only provided as an exemplary use context for an power control unit/power supply module according to embodiments of the present disclosure, in order to provide a concrete example of a context for which such unit/module may be designed and fabricated. It will be appreciated herein that nothing herein is intended to limit the utility of a power control unit according to embodiments of the present disclosure to the specific context of aerosol provision systems, such as that shown schematically in FIG. 1, and that the principles described herein for design and fabrication of a power control unit may be applied in respect of a device/system from any field of electrical devices in which a power supply unit/module (e.g. a SMPS) may be implemented.

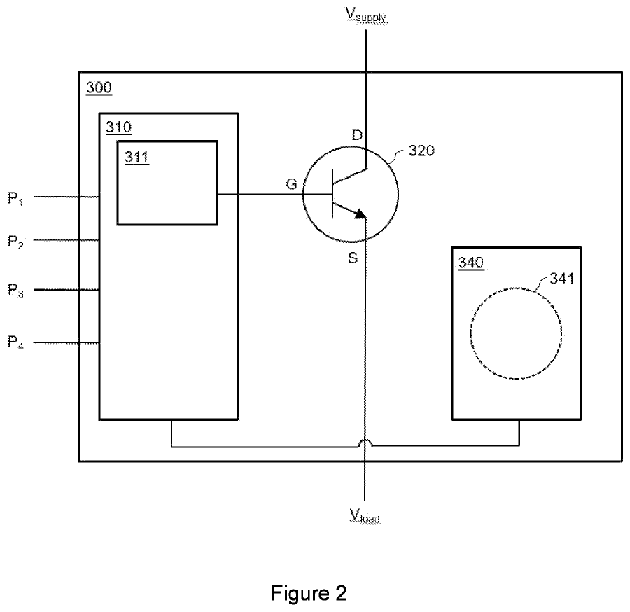

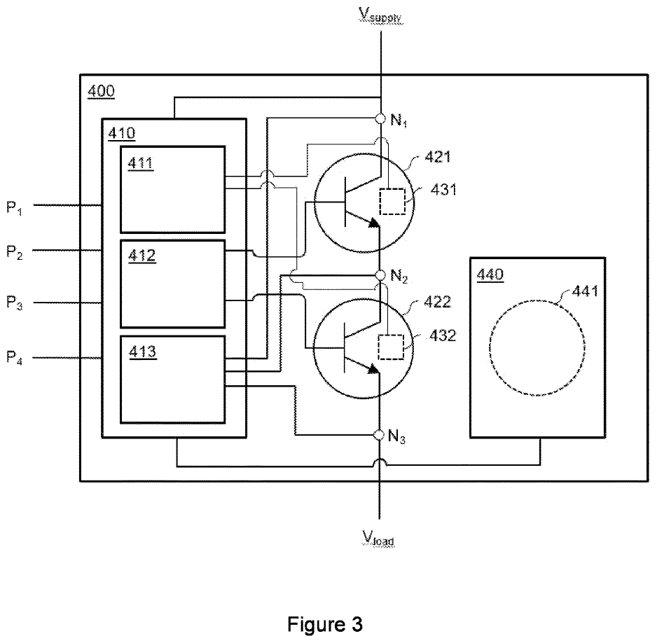

In order to allow electrical power from a power source to a load in an electrical/electronic device or system, switching circuitry may be provided which can open and close the circuit path between the power source and the load. In an aerosol provision system context such as shown schematically in FIG. 1 and described in the accompanying text, the load may comprise an aerosol generator 48 such as a resistive heating element, but it will be appreciated the load could in principle be associated with any functionality associated with the aerosol provision system (or another device in which a power control unit according to the present disclosure is comprised, as described further herein), and the specific functionality to be supported is not of particular significance to the principles of fabrication and operation of a power control unit as described herein. Aspects of the present disclosure are particularly directed to embodiments in which a power control unit comprises one or more solid-state switches, and thus embodiments of the power control units described herein may be particularly applied in contexts involving supply of power from a power supply to a load using solid-state switches (including in contexts outside of the field of aerosol provision systems). Solid-state switches (also known as ‘relays’) typically provide a gate of variable resistance between a collector/drain terminal (connected to supply voltage) and an emitter/source terminal (connected to a load), wherein the resistance of the gate varies in dependence on a voltage applied to a base/gate terminal. These terminal designations may be used interchangeably herein. Typically, solid-state switches are implemented as field-effect transistors (FETs), of which there exist a range of sub-types, including the metal-oxide-semiconductor field-effect transistor (MOSFET), junction field-effect transistor (JFET), and metal-semiconductor field-effect transistor (MESFET). Approaches as described herein may be applied to power control units comprising these, and/or other FET types, including new types yet to be developed. A FET is typically characterised by low on/closed resistance and high off/open resistance on the drain-to-source electrical path,, high gate-to-drain current resistance (thus isolating the control circuitry and the current path through the main gate between drain and source), and a low power-draw for switching control signals used to switch the gate state between open/off and closed/on, or vice-versa. FIG. 2 shows an exemplary implementation of a power control unit comprising a power controller package 300 (‘controller package’), comprising a single solid state switch/FET 320, control logic 310 comprising a FET control module/functional unit 311, and an airflow sensor 340 with a port 341 for fluid connection to a region of an aerosol provision system which is part of an airflow path in which a pressure drop is induced during user draw. In this example, the control logic 310, FET 320, and airflow sensor 340, are implemented in the same package 300, however this is merely exemplary, and these components may be separately provided (e.g. as part of separate assemblies, for example on discrete silicon substrates) which are provided with suitable electrical interconnects (e.g. wires or other conductive lines). The FET 320 comprises a switchable solid-state gate disposed between the drain/collector terminal (D) and the source/emitter terminal (S); and a gate/base terminal (G), at which the control logic 310 can apply a voltage e.g. (between terminal G, and terminal S or ground), to control the conductivity of the gate between terminals D and S. The drain terminal S is connected to supply voltage V_{supply} (e.g. being directly or indirectly connected to the battery of a device in which the power controller package 300 is implemented), and the source terminal S is connected to an electrical load (e.g. a heater or other aerosol generator, in an aerosol provision system context). The gate terminal G is connected to FET control unit 311 of control logic 310, the FET control unit 311 being configured to provide a variable voltage to terminal G to switch the FET gate between closed/on, and open/off states. As is known to the skilled person, the state of a FET in use is partly characterised by various electrical parameters, including I_{D} (current passing the gate), R_{DS} (resistance across terminals D and S), and V_{DS} (voltage across terminals D and S). Typically, the operating characteristics of a solid-state switch/FET are as follows (the actual values of the various parameters being characterised, unless specified otherwise, by the particular design/model of FET and environmental factors). When the voltage applied to the gate terminal (i.e. V_{GS}) is below a threshold voltage (i.e. V_{TH}), the current between D and S (i.e. I_{D}) is low (i.e. at/towards the bottom end of the normal operating range), and the resistance between D and S (i.e. R_{DS}) is high (i.e. at/towards the top of the normal operating range), and the voltage across D and S (i.e. V_{DS}) is thus high (i.e. at/towards the top of the normal operating range). This regime, where V_{GS}<V_{TH}, may be referred to as operation in ‘cutoff mode’. In the regime where V_{TH}<V_{GS}<V_{SAT} (where V_{SAT} is the ‘saturation voltage’), I_{D}, R_{DS}, and V_{DS}, will typically vary with varying V_{GS}. Typically, in this regime, which may typically be referred to as ‘linear mode’, R_{DS} may typically vary linearly or quasi-linearly with varying V_{GS}, with according variation in I_{D} and V_{DS}. In the regime where V_{GS}>V_{SAT}, R_{DS} substantially ceases to vary as V_{GS} continues to increase above V_{SAT}. This regime may typically be referred to as ‘saturation mode’. Thus the current flow across the gate (i.e. I_{D}) and the power supplied to the load (e.g. a heater) tend to their maximum values in saturation mode. Thus, in an exemplary use case, the control logic 310 is operable to control the power delivered to the load from the power supply/battery by varying the voltage supplied to the gate (G), in dependence on signals received at the control logic 310 from an airflow sensor 340. It will be appreciated that in other examples, the power controller package 300 may not comprise an airflow sensor 340, and signals to indicate the desired switching state may be provided to the control logic 310 by a different activation element, such as a manual user input element (e.g. a button), or a further controller (e.g. an MCU or ASIC), which may be integrated into the power control package 300, or connected via one or more input pins (e.g. a bus) associated with the power control package 300. Four exemplary input pins P1, P2, P3, and P4, are shown in FIG. 3, but it will be appreciated the number of pins may be selected by the skilled person dependent on particular requirements of a specific use case. Where an airflow sensor 340 is used, this may comprise, for example, a MEMS sensor (such as a MEMS pressure sensor), comprising a port 341 to expose a pressure-sensitive element to a pressure drop induced in an aerosol provision system when a user puffs on the device. Depending on the pressure sensor design, a further port (not shown) may expose the pressure sensitive element to a reference pressure (e.g. ambient pressure). The control logic 310 is configured to receive signals from the sensor/manual user input element, or a further controller, and output a switch control voltage (V_{GS}) to the FET gate terminal (G) to control the gate state. Thus, in some embodiments, the airflow sensor 340 outputs to the control logic 310 a signal which is proportional to a pressure drop sensed at the port 341. The FET control unit/functional unit 311 (which may be implemented in software, where the controller is an MCU, or may comprise a functional unit/module of an ASIC), is operable to provide a switch-control voltage to the FET gate terminal (G), the amplitude of which varies in dependence on the input signal received from the activation element. Thus when the control logic 311 determines the input signal has exceeded a trigger condition (e.g. a threshold), it may provide a continuous or pulsed (e.g. square wave) control signal V_{GS}, of a magnitude greater than V_{TH}. For example, pulsed signal at peak amplitude of V_{GS}=V_{SAT} or V_{GS}>V_{SAT} may be used, with the duty cycle and/or periodicity of the pulsed signal being controlled to vary the power supplied to the load between 0 W and the peak power determined by the supply voltage, maximum supply current, and the losses in the circuit path. This approach may be used to implement a pulse-width modulation scheme for power supply to the load, using approaches known to the skilled person.

It will be appreciated the above examples of operation of the configuration of FIG. 2 are only for context, and the principles herein are applicable to a power control unit/package 300 comprising at least one solid-state switch, regardless of the specific way the switch is controlled in normal operation to supply power to the load (e.g. whether or not an actuation element such as an airflow sensor 340 is included).

Solid-state switches (such as FET 320 shown in the exemplary power control unit of FIG. 2) may degrade and fail due to a variety of mechanisms, which may be due to dynamic loading above various safe limits of current, voltage, and/or total power dissipation, or due to environmental impacts (e.g. damage due to external factors). As a non-exhaustive set of examples of dynamic-loading failure modes, and without wishing to be bound by any particular physical theory, it is thought that a maximum operating voltage of the FET may be exceeded, leading to material disintegration/dielectric breakdown via short circuit; and/or a maximum rate of voltage rise may be exceeded (e.g. due to a rapid transient spike in voltage caused by, for example, electrical noise or RF interference), causing insulation between the gate and the body of the FET package to be degraded; and/or power dissipation may exceed a threshold rate, causing degradation of materials (e.g. de-soldering and/or de-bonding of components from a die). The latter may be caused by a maximum operating current being exceeded, for example by a short-circuit condition on the load. Dynamic loading in unsafe regimes may lead to rapid (e.g. near-instantaneous) failure, or may degrade the FET more slowly (e.g. over a plurality of switching cycles) such that it continues to function with impaired operational characteristics. Even if safe loading limits are not exceeded, degradation may still occur due to aging as the number of switching cycles increases cumulatively. Environmental impacts such as overheating, water ingress, contamination, and radiation damage, may also degrade materials comprised in the FET leading to failure, or pre-failure degradation.

A solid-state switch/FET, such as FET 320 of FIG. 2, may be in one of a plurality of different operating states, depending on a degree of degradation. These include a complete failure state, which may be categorised by the failure of the FET gate to respond to control signals from the control logic 310. For example, the FET may be in a complete failure state, where the gate resistance (i.e. R_{DS}) is high (e.g. at or above its nominal ‘open/off’ rating), and cannot be reduced by applying a control voltage (e.g. a control voltage at V_{TH}<V_{GS}<V_{SAT}, V_{GS}=V_{SAT}, or V_{GS}>V_{SAT}). This operating state may be referred to as an ‘open failure’. In other circumstances, a complete ‘closed failure’ operating state may be considered to have occurred where significant current (i.e. I_{D}) can pass the gate of the FET despite the control voltage (i.e. V_{GS}) being below the threshold voltage (i.e. V_{TH}). In some circumstances, the gate resistance (i.e. R_{DS}) in an open-failure state may be low (e.g. at or below its nominal ‘open/off’ rating) even when V_{GS} is substantially zero. A partial closed-failure state may occur where R_{DS} remains between the nominal values in the ‘on’ and ‘off’ states despite the control signal voltage V_{GS} being below the threshold V_{TH}. Complete or partial closed-circuit failures may be considered particularly dangerous failure states in operating contexts where the load comprises a heater, since the FET 320 cannot be switched to an open-circuit state by the controller 310 to turn off the supply of current and thus terminate heating. This may lead to overheating, causing damage to the device, and potentially injury to a user and/or risk of fire.

It is recognised that a FET may be in a degraded operational condition without being/prior to entering a complete failure state (e.g. open- or -closed circuit failure). A degraded operational condition may be defined as one in which physical degradation of the FET has caused the response behaviour (i.e. response to differing control voltage V_{GS}) to vary appreciably from the nominal behaviour of the FET in the new/virgin/pristine/as-manufactured state. This variation may be characterised as a degradation-induced drift over time in at least one operating parameter of the FET. For example, the curve representing the relationship between control voltage (i.e. V_{GS}) and resulting gate voltage (i.e. V_{GS}) for the same supply voltage at the drain terminal (D) may drift over time/use, as may the values of V_{TH} and/or V_{SAT}. Indeed, depending on the nature of the degradation, any of the defining operating characteristics/parameters of the FET (including scalar values, and rates of change of various orders) may drift as the FET ages, and may also be induced/accelerated by dynamic loading in regimes exceeding the rated operating limits (e.g. limits for V_{GS}, V_{DS}, and I_{D}) as defined by manufacture.

The inventor has recognised that in power control units comprising solid-state switches/FETs, and particularly those where the load under control comprises a heater (such as in many aerosol provision systems), strategies to mitigate the risk of complete FET failure and/or prevent complete failure of FETs and/or monitor FET degradation state are of interest.

Thus, according to embodiments of the present disclosure, there is provided a power control unit configured for use in an electrical/electronic device (such as an aerosol provision system), the power control unit comprising: at least one power supply terminal for connection to an electrical power supply; at least one load terminal for connection to an electrical load; an electrical current path configured to connect the at least one power supply terminal to the at least one load terminal; and a plurality of switches connected in series along the electrical current path, wherein the power control unit comprises control logic configured to independently switch each of the plurality of switches between an open-circuit state and a closed-circuit state; wherein the control logic is configured to supply electrical current to the load terminal via the electrical current path; and wherein the control logic is further configured to determine if at least one first switch of the plurality of switches is in an adverse operating state, and to modify an aspect of the provision of electrical current to the load terminal via the electrical current path on the basis of said determination.

FIG. 3 shows a power control unit 400 according to embodiments of the present disclosure. As in the power control unit of FIG. 2, the power control unit 400 comprises control logic 410, and an optional airflow sensor 440, as described in association with FIG. 2. A plurality of solid-state switches/FETs is distributed in series between a power supply terminal (V_{supply}), configured to be connected directly or indirectly to a power source (e.g. a battery 26 as shown in FIG. 1) and a load terminal (V_{load}), configured to be connected directly or indirectly to a load (e.g. an aerosol generator such as a heater 48 as shown in FIG. 1). The control logic 410 comprises various functional modules/units. These are shown schematically in FIG. 3 as being spatially distinct, and whilst in some instances, the functionality of each functional unit may be provided by a different circuit module (e.g. series of cells and electrical interconnects implemented as part of an ASIC), in other instances, the functionality of one or more of the functional units (or all the functional units) may be provided by the same circuitry/hardware, with each functional unit supported virtually by different firmware/software routines (e.g. where the power control unit 410 comprises a microcontroller unit (MCU) implementing one or more routines defined in firmware/software). In other words, the reference to different ‘functional units’ of the power control unit 410 is intended herein to allow different functionalities of the power control unit 410 to be described, without necessarily implying each functional unit is implemented using discrete circuitry or software elements. The gate terminals (G) of each of the switches are independently connected to a FET control unit 412, configured to provide an AC/pulsed or DC driving voltage to the gate of each each switch to toggle it between open and closed states (as described in accordance with FIG. 2). The standard driving voltage parameters in normal usage can be configured according to known approaches, taking into account the characteristics of the specific switches used (i.e. as defined by the manufacturer). Two solid-state switches (e.g. FETs) 421 and 422 are shown in the example of FIG. 3, but it will be appreciated that in other embodiments, any number of switches may be provided in series, with the number of measurement nodes and switch state sensors scaled accordingly, with an electrical measurement node defined between neighbouring pairs of switches, and with each switch connected to the FET control unit 412.

In any of the embodiments described herein, the power control unit 400 may comprise an application specific integrated circuit, ASIC, package, in which at least the control logic 410 is fabricated onto a single die/chip/wafer, or distributed among different dies/chips/wafers packaged into the same casing. Optionally, the plurality of switches with associated electrical measurement nodes and/or switch state sensors defined on one or more separate discrete elements (e.g. circuit boards) connected to the control logic 410 by appropriate electrical interconnects. In some embodiments, the switches are integrated with the control logic 410 on a single semiconductor die (e.g. a silicon die), and the controller package 400 may comprise a high power density ASIC power controller/SMPS. Where the controller package 400 comprises an ASIC, the functions described in the embodiments herein may be implemented using chip design and fabrication processes known to the skilled person. For example, the control logic (e.g. in terms of how switching control signals are provided in response to inputs, and how switch degradation monitoring approaches described herein are implemented) may be translated into a hardware description language (e.g. Verilog or VHDL), in a register-transfer level (RTL) design stage. There may typically follow a functional verification stage, where the control logic is simulated (e.g. via bench testing, formal verification, emulation, or creating and evaluating an equivalent pure software model). There may typically follow a logic synthesis stage where the RTL design is transposed/compiled into a set of standard or custom cells, typically derived from a standard-cell library of logic gates configured to perform specific functions, to form a gate-level netlist. In a placement stage, the gate-level netlist is processed to derive a placement of the cells on a die (e.g. a silicon die). During placement, the cell positioning is typically optimised for efficiency and robustness. In a routing stage, the netlist is typically used to design appropriate electrical connections between the standard cells, to provide the control logic. The output of the placement and routing stages is typically the derivation of the photo-mask(s) (‘masks’) which will be used to fabricate the circuitry of the ASIC package (e.g. the control logic 410) on the die material.

The manner in which the FET control unit 412 is configured to switch the states of the switched by supplying a control voltage (i.e. V_{GS}) to the respective gate of each switch is context-dependent, and may be based on an output signal received by the FET control unit 412 from an actuation element (e.g. a manual activation element such as a button, or one or more sensors), or may be based on internal signal flows/algorithms implemented by control logic 410 (e.g. so that switches are triggered on and off according to a predefined schedule). The power control unit 400 may comprise a wired or wireless data connection to one or more external computing devices, which output signals to terminals of the controller package 400 on the basis of which the FET control unit 412 is triggered to switch the states of the switches. Thus power control unit 410 may optionally comprise control logic (e.g. comprised in FET control unit 412) configured to detect a trigger signal provided by an actuation element, and to control the supply of electrical current from an external power supply connected to the power supply terminal (i.e. (V_{supply}), to the load terminal (i.e V_{load}), via the electrical current path passing through the plurality of switches on the basis of the trigger signal. In some embodiments, such an actuation element may be integrated into the power control unit 400, as shown in FIG. 3, where an airflow sensor 440, as described in accordance with FIG. 2, is integrated into the power control unit 400, which may comprise an ASIC package. In some embodiments, such an ASIC package may comprise an airflow sensor implemented as a MEMS pressure sensor or microphone, and the power control unit 400 may in these contexts be referred to as an aerosol provision system power control unit.

As described above, in embodiments of the present disclosure, the control logic 410 defined in the power control unit 410 is configured to determine if at least one first switch (e.g. FET) of the plurality of switches is in an adverse operating state, and to modify an aspect of the provision of electrical current between the power supply and load terminals (i.e. V_{supply} and V_{load}) on the basis of said determination. In some embodiments, the adverse operating state comprises a failure state, and the control logic 410 is configured to determine at least one first switch of the plurality of switches is in an adverse operating state by determining the at least one first switch has failed. The failure state may comprise a complete failure state, as described further herein. Thus, in some aspects of these embodiments, the power control unit 400 is configured to determine at least one first switch has failed non-reversibly in a closed-circuit state. In some aspects of these embodiments, the power control unit 400 is configured to determine the at least one first switch has failed non-reversibly in an open-circuit state.

FIG. 3 shows schematically three nodes N1, N2, and N3, respectively positioned at locations prior to the two switches 431 and 422, between the two switches, and after the two switches, on the current path between power supply and load terminals. An electrical measurement unit 413 associated with the controller 410 is connected to each of the nodes N1, N2, and N3, to allow electrical parameters associated with the switches 421 and 422 to be determined. For example, the drain-to-source voltage (i.e. V_{DS}) of switch 421 can be measured across nodes N1 and N2, and the drain-to-source voltage (i.e. V_{DS}) of switch 422 can be measured across nodes N2 and N3. Optionally, the current (i.e. I_{D}) through the plurality of switches may be measured at a position between V_{supply} and V_{load}, via ammeter circuitry connected to the electrical measurement unit 413 (circuitry not shown in FIG. 3). By providing hardware or software interconnects between the FET control unit 412 and the electrical measurement unit 413, the gate to source voltage (i.e. V_{GS}) for each switch can be determined by the electrical measurement unit 413. Typically, the electrical measurement unit 413 is configured to determine the supply voltage connected to the power supply terminal using approaches for power-supply output voltage measurement known to the skilled person. Other electrical parameters as described herein may be determined by the electrical measurement unit 413 using approaches known to the skilled person. What may be considered significant is that these parameters can be determined independently for each of the plurality of switches. The electrical measurement unit 413 and associated circuitry (e.g. connecting to nodes N1, N2, and N3) may be considered to comprise a separate switch status sensor associated with each one of the plurality of switches.

In some embodiments, the electrical measurement unit 413 may determine a failure state of a given first switch of the plurality of switches by measuring the drain to source voltage (i.e. V_{DS}) across the switch at appropriate measurement nodes, and determining if this is in the expected range based on a predefined control voltage (i.e. V_{GS}) applied to the gate of the respective switch. Failure may be identified by applying a control signal at a single voltage, or swept over a range of voltages, and comparing the actual voltage(s) (i.e. V_{DS}) associated with the control voltage(s) V_{GS}, with the expected value(s) of V_{DS} for the same value(s) of V_{GS}, based for example on a calibration curve of V_{DS} Vs V_{GS} for the switch (which may be derived via experimentation or provided by the switch manufacturer). The electrical measurement unit 413 may optionally comprise a temperature sensor, power-supply voltage sensor, and switch current (I_{D}) sensor to allow the calibration curve to be corrected/selected to take into account the ambient temperature, supply voltage, and switch current. Taking into account the ranges of drain-to-source voltage (i.e. V_{DS}) associated with each of the cutoff, linear, and saturation modes of the switch as manufactured; a closed-circuit failure may be determined to have occurred if V_{GS} is in a range associated with either of linear or saturation mode operation when the control voltage (i.e. V_{GS}) is in a range associated with cutoff mode operation, or if V_{GS} is in a range associated with saturation mode operation when V_{GS} is in a range associated with linear or cutoff mode operation; and a open-circuit failure may be determined to have occurred if V_{GS} is in a range associated with either of cutoff or linear mode operation when V_{GS} is in a range associated with saturation mode operation; or if V_{GS} is in a range associated with cutoff mode operation when V_{GS} is in a range associated with linear or saturation mode operation, or if V_{GS} is in a range associated with cutoff or linear mode operation when V_{GS} is in a range associated with saturation mode operation. In other words, if the drain-to-source voltage (i.e. V_{DS}) across a given switch is lower than expected based on the normal value(s) for a given control voltage (i.e. V_{GS}), the electrical measurement unit 413 may determine the switch is in an open-circuit failure, or if V_{GS} across a given switch is greater than expected based on the normal value for V_{GS}, the electrical measurement unit 413 may determine the switch is in an closed-circuit failure. More generally, a switch failure may be determined to have occurred if V_{DS} does not respond in the typical manner to a change in V_{GS}.

Though not shown in FIG. 3, the controller package 400 may comprise switchable electrical lines enabling each of switches 421 and 422 to be independently connected to the supply voltage and the load (or to ground). Thus in the context of FIG. 3, if a first switch 421 has undergone complete open-circuit failure, such that no supply voltage can be supplied via the first switch 421 to the second switch 422, the supply voltage may be switched directly to node N2 to bypass the failed first switch 421, allowing the electrical parameters associated with the gate between drain and source of the second switch 422 to be measured as described above. Similarly, if a second switch 422 has undergone complete open-circuit failure, such that no connection from the source terminal of a first switch 421 can be made to the load/ground via the second switch 422, the load/ground may be switched directly to node N2 to bypass the failed second switch 422, allowing the electrical parameters associated with the gate between drain and source of the first switch 421 to be measured as described above

According to the approaches described above, if a first switch of the plurality of switches (e.g. one of switches 421 and 422 in the two-switch embodiment shown in FIG. 3) is determined to have failed, the control logic 410 may be configured to modify the provision of electrical current to the load terminal by switching at least one second switch of the plurality of switches to an open-circuit state based on determining the at least one first switch has failed, (e.g. via provision of an appropriate control voltage V_{GS} to the second switch, which will typically comprise the removal of the control voltage from the gate of the second switch). In response to detecting failure of one or more first switches, one or more second switches, which in some instances comprises all other switches of a plurality of switches on the current path between the power supply and load terminals, may be triggered to their open-circuit state (e.g. by removing gate voltages), and the power control unit 400 may be configured to maintain this condition regardless of whether signals are received at the power control unit 400/control logic 410 which would usually trigger the FET control unit 412 to close one or more switches.

When at least one switch is determined to be in an adverse operating condition, for example a failure state, the controller 400 may be configured in some embodiments to provide an alert signal. For example, the controller 400 may comprise a visual, audio, or haptic feedback unit, which is triggered to provide an alert to a user to indicate switch failure, or may be configured to provide signals (e.g. via one or more output pins) to an external computing device or feedback unit. The alert may generally indicate a switch failure has been detected, and may optionally more specifically indicate which of the switches has failed, and optionally whether the failure is complete, complete open failure, complete closed failure, or partial failure, to provide diagnostic information to a user.

The electrical measurement unit 413 of the power control unit 410 may be triggered to carry out monitoring/checks of whether each of the plurality of the switches is in an adverse operating state (e.g. a failure state) according to one of a number of approaches, which are applicable to all embodiments described herein. For example the control logic 410 may trigger checking of each switch on a periodic schedule, or may trigger checking of each switch as part of normal power control operation (e.g. as an initial step after signal has been received by the FET control unit 412 indicating one or more switch states should be changed), or the control logic 410 may trigger the electrical measurement unit 413 to carry out checking of the plurality of switches if one or more operational parameters associated with the power control unit 400 are determined to have changed beyond a predefined tolerance. For example, the electrical measurement unit 413 may monitor current (i.e. I_{D}) through the switched circuit path, and determine if the response of the current (e.g. in peak amplitude and/or rate of change) is different to the expected response given the battery charge state, the characteristics of the load, and the switching pattern applied by the FET control unit 412. An abnormal response may be determined if, for example, current continues to pass after one or more switches have been triggered to turn off, or current fails to rise to the expected level after all the switches have been turned on, or if the rate of rise or fall of current when switches are respectively closed and opened is more than a predefined threshold amount faster or slower than the expected value, as defined for example by testing when the controller 400 is first manufactured.

The inventor has recognised that whilst mitigating failure of one or more first switches via switching the state of one or more second switches in a power control unit 400 to an open-circuit state, and optionally providing a failure alert, may provide enhanced device safety, it may be desirable to incorporate functionality to the power supply unit 400 which enables early detection of adverse switch operating conditions, before complete failure occurs. Thus in some embodiments, the control logic 410 is configured to determine at least one first switch of the plurality of switches is in an adverse operating state by determining, prior to failure (e.g. complete failure) of the at least one first switch, that the at least one first switch is in a degraded operational condition (as defined further herein).

Accordingly, in these embodiments, the control logic 410 is configured to receive signals from at least one first switch status sensor configured to detect a first parameter associated with operation of at least one first switch 421, 422, wherein the control logic 410 is further configured to determine an indication of an operational condition of the at least one first switch on the basis of the received signals, and to determine whether at least one first switch of the plurality of switches is in an adverse operating state on the basis of the indication of operational condition. In approaches according to these embodiments, the control logic 410 is configured to receive signals from one or more switch status sensors, wherein each switch status sensor is configured and positioned relative to a respective first switch such that the signals output by the switch status sensor are indicative of at least one operating parameter of the at least one first switch. For example, in embodiments described further herein, a switch status sensor may be configured to output signals which are indicative of one or more electrical and/or environmental (e.g. temperature) parameters associated with the functioning of a given first switch of the plurality of switches (in that characteristics of the output signals change as switch functioning changes). According to one or more approaches described herein, the signals output by the switch status sensor are received by the control logic 410, which is configured to determine whether a first switch associated with the switch status sensor is in an adverse operating state (e.g. in a degraded operational condition). Typically, this determination is based on comparing, at the control logic 410, one or more parameters derived from output signals from one or more switch status sensors associated with a first switch comprised in the power control unit 400 with the value/value of said parameter(s) associated with one or more reference switches of the same type and of known operating condition/state. The ‘reference’ switch may comprise the same switch in its as-manufactured/pristine/virgin condition, and the reference value(s) may be derived for the switch by the control logic 410 of the power control unit 400 as part of initialisation of the power control unit 400 when it is first commissioned. As described further herein, the parameters derived from the output signal may be directly representative of physical parameters such as current, voltage, power, frequency, capacitance, resistance, conductance, inductance, or impedance, associated with electrical path elements of the respective switch (such as electrical path elements between the main terminals of the switch, and/or sub-paths within the switch), or, for example, the temperature(s) during operation of one or more elements of the switch, such as the gate or the die/chip/wafer in a FET context. Alternatively, the control logic 410 may be configured to derive one or more secondary parameters from one or more of these direct physical parameters, for example using an appropriate equation or algorithm (for example via a frequency-domain transform of a time-varying signal output from a switch status sensor). It will be appreciated that principles of measurement of electrical parameters as described herein may be carried out using measurement circuitry known to the skilled person (i.e. where measurements of electrical parameters are described herein, the electrical measurement unit 413 can be configured with functionality to carry out these measurements using approaches known to the skilled person, for example, using appropriate configurations of standard cells where the power control unit 400 comprises an ASIC package implementing control logic 410).

Typically, one or more switch status sensor(s) may be individually associated with respective ones of the at least one first switch, at least in that the measurements made by the sensor(s) enable operating parameters of each of the at least one first switch to be independently derived. In other words, the control logic 410 may be configured to determine a separate indication of the operational condition for each respective one of the at least one first switch. In other instances, respective ones of the at least one first switch status sensors may be individually associated with more than one of the at plurality of first switches, such that the measurements made by a single switch status sensor are influenced by the operating condition of more than one of the plurality of switches. In either scenario, the control logic 410 is configured to separately determine an adverse operating state for each respective one of the at least one first switch.

According to a first set of embodiments, the at least one switch status sensor is configured to measure/detect at least one electrical parameter associated with the operating state of the at least one first switch. In these embodiments, the switch status sensor for a given first switch typically comprises the electrical measurement unit 413 and associated electrical connections, and as such, may act as a switch status sensor configured to independently measure electrical parameters for each of a plurality of first switches. In one embodiment, the drain-to-source voltage (i.e. V_{DS}) for a given first switch at a given control voltage (i.e. V_{GS}) may be used to as the indicator of operating condition used by the control logic 410 to determine the degree of degradation of said switch, as described in [1]. Alternatively, or in addition, the maximum peak amplitude of the drain to source current (i.e. I_{D}) ringing at the turn-off transient (i.e. when the control voltage (i.e. V_{GS}) is removed from the gate of a given switch by the FET control unit 412) may be used to as the indicator of operating condition used by the control logic 410 to determine the degree of degradation of said switch, as described in [2]. Alternatively, or in addition, the control logic 410 may be configured to determine the presence of an adverse operating state associated with one or more first switches by analysing the frequency response of the drain to source voltage (i.e. V_{GS}) as the gate current (I_{D}) is driven by the FET control unit 412 at a certain, predefined reference frequency. For example, a square wave control signal may be applied to the gate (G) of a given switch at a voltage amplitude which is associated with either linear or saturated operating regimes, and the frequency components of V_{GS} may be analysed to determine an indicator of operating condition, and thus a degree of degradation, based on the amplitudes of different frequency components (e.g. the first to third order components). In one implementation, the power control unit may be configured to determine a degree of degradation of at least one first switch using the Volterra series transform for the output signal of the switch, as described in [3]. Experimentation using reference switches of the same model as the switches used in the power control unit, having known degrees of degradation (e.g. expressed as a percentage of cycles to failure), may be used to parameterise a model used by the control logic 410 to quantify the degree of degradation as described in [3]. The degree of degradation may be expressed as a percentage of cycles to failure.

Alternatively, or in addition to the use of electrical parameters to determine operating condition of a given first switch, in some embodiments the switch status sensor may comprise a temperature sensor, and the temperature characteristics of the switch, part of the switch, and/or a region of the power control unit 400 in the vicinity of the switch, may be used to determine a degree of degradation. Without wishing to be bound by any particular theory, it is thought that some FET degradation modes are associated with detachment of the gate from the die, causing a degraded FET to exhibit different heat transfer characteristics between the gate and the die when compared to a pristine/virgin/as-manufactured FET. Because heat conduction away from the gate is typically impaired when the gate is partially detached from the die, higher gate operating temperatures are typically associated with the gate of a degraded FET, given fixed power dissipation and ambient temperature values. Thus, in some embodiments, the peak gate temperature and/or rate of change of gate temperature at a reference power dissipation value may be used to determine the degree of degradation of the FET, for example, according to the approach set out in [4]. FIG. 3 shows optional temperature sensors 431 and 432, respectively associated with switches 421 and 422, the temperature sensors being connected to a temperature control unit 411 (though the functions of the temperature control unit 411 could also be integrated into the electrical measurement unit 413). Where a temperature sensor is associated with a given first switch, this may typically be integrated into or attached to the gate to directly measure gate temperature (as in [4]), but may also be positioned on the die proximate to the gate (to infer the degree of heat transfer to the die from the gate). Temperature measurements derived using a switch status sensor may be calibrated/normalised by the temperature measurement unit 413 using a reference ambient temperature sensor measured at a position on the die away from the switch, or external to the power control unit 400 (and connected to it, for example, using one or more input terminals), or using one or more temperature values measured by the switch sensor at a time when the switch is not passing current.

In embodiments of the present disclosure, the control logic 411 may be configured to modify the provision of electrical current to the load terminal by switching at least one second switch of the plurality of switches to an open-circuit state based on determining the at least one first switch is in a degraded operational condition. In some instances, this may comprise switching one or more second switches to an open state (as described above in relation to detection of switch failure), or may comprise continuing to allow switching of the plurality of switches to a closed state to pass current to the load, under modified operating conditions. For example, in embodiments where the control logic 410 is configured to determine one or more first switches is in a degraded operational condition, without complete open-or closed-circuit failure having occurred, the control logic 410 may further quantify the degree of degradation, and modify one or more aspects of operation of the power control unit 400 on this basis. For example, the estimated degree of degradation of a given first switch may be quantified as a percentage of cycles to failure, which the control logic 410 is configured to determine, based on values derived for switches which have been cycled to failure whilst measuring the same switch operating parameter(s). For example, a calibration curve of a given operating parameter (e.g. gate temperature, rate of change of gate temperature, amplitude of different frequency components of V_{GS}, drain to source voltage, or peak amplitude of the drain to source current (I_{D}) ringing at the turn-off transient), derived from pristine condition to complete failure for one or more samples for the same switch type, under the same or similar supply voltage conditions and ambient temperature in which the power supply unit 400 is to be used, may be used to estimate a percentage of elapsed lifetime (expressed, for example, in cycles, or watt-hours) until failure for a given first one of the plurality of switches. When the lifetime exceeds a certain threshold (for example, more than 50%, more than 60%, more than 70%, more than 80%, more than 90%, or more than 95%), the control logic 410 may modify operation of the power control unit 400 by, for example, reducing the operating power, reducing the switching frequency, or reducing the value of a safety cutoff temperature at which the control logic 410 sets at least one switch to an open-circuit condition to switch off the supply of power to the load.

Thus, according to embodiments of the present disclosure, the power control unit 400 (e.g. a power control ASIC package 400) may be configured to estimate a remaining lifetime of at least one first switches, based on the indication of the operational condition of the at least one first switch. In some embodiments, the estimated lifetime may comprise an estimated lifetime until the at least one first switch is in a degraded operational condition. In some embodiments, the estimated remaining lifetime may comprise an estimated lifetime until the at least one first switch fails (e.g. enters a complete failure state, as described further herein). In some embodiments, the estimated remaining lifetime may be expressed as a number of opening and closing cycles of the one or more first switches until failure or entry into a degraded operational condition is estimated to occur. In some embodiments, the estimated remaining lifetime may be expressed as a duration of current flow (e.g. expressed in units of power per unit time, such as watt-hours) through the one or more first switches. In some embodiments, the estimated remaining lifetime may be expressed as an amount of energy transmitted through the one or more first switches. As set out above, the parameterisation of remaining lifetime is typically achieved using data gathered via experiments conducted on switches of the same type as the switch whose remaining lifetime is to be estimated by the control logic 410. Test switches may be characterised using instrumentation corresponding to the switch state sensors and temperature and/or electrical measurement units described herein, with the test switches being cycled to failure under different loading conditions (e.g. supply voltage, peak power output, ambient temperature, and switching speed/duty cycle), which are representative of the use context in which the power control unit 400 is to be used. As each test switch is cycled to failure, at least one calibration curve is then derived plotting a certain ‘lifetime’ parameter (e.g. number of on/off cycles, power per unit time, duration of current flow, expressed for example in watts multiplied by time) over the lifetime to failure of the switch. During this experimentation, analysis of measured electrical/environmental parameters may be used to determine at what percentage of the elapsed lifetime the switch typically enters a degraded operating condition (as determined, for example, by detection of abnormal operating temperature, abnormal current flow, abnormal drain to source voltage, or abnormal on/off response time), and/or at what percentage of elapsed lifetime the switch typically enters a complete failure (e.g. open or closed failure) state. Thus, in use of the power control unit 400, the control logic 410 may use stored calibration information (e.g. in the form of one or more look-up tables), or one or more models or equations derived from it, to determine an estimated remaining lifetime based on one or more determined operating parameters/indications of operating condition during use of the power control unit 400.

Thus, in embodiments of the present disclosure, the control logic 410 may be configured to modify the provision of electrical current to the load terminal by switching at least one second switch of the plurality of switches to an open-circuit state based on determining a previously estimated remaining lifetime of at least one first switch has elapsed. At a given point in time, a remaining lifetime may be determined, which is set to be less than the estimated remaining lifetime until the first switch enters a degraded operational state, or undergoes complete failure. Switching at least one second switch to an open circuit condition when this estimated remaining lifetime has elapsed may provide enhanced safety, by deactivating the power control unit 400 before an adverse operating condition of any switch is reached. In any of the embodiments described herein, the power control unit 400 may be configured to modify the aspect of the provision of electrical current to the load terminal by reducing the electrical power of a supply of electrical current transmitted to the load terminal, based on determining a previously estimated remaining lifetime of at least one first switch has elapsed.

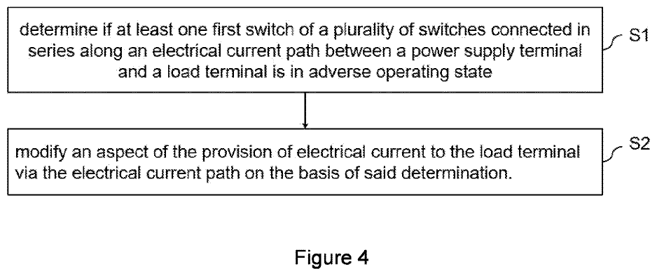

Thus there has been described a power control unit for controlling a supply of power on an electrical current path configured to connect at least one power supply terminal for connection to an electrical power supply to at least one load terminal for connection to an electrical load, via a plurality of switches connected in series along the electrical current path. With reference to FIG. 4, a method is also provided of operating such a power control unit to control a supply of power on an electrical current path configured to connect at least one power supply terminal for connection to an electrical power supply to at least one load terminal for connection to an electrical load, via a plurality of switches connected in series along the electrical current path; wherein the method comprises operating control logic comprised in the power control unit, the control logic being configured to supply electrical current to the load terminal via the electrical current path, to cause the control logic to independently switch each of the plurality of switches between an open-circuit state and a closed-circuit state; wherein the method comprises, in a first step, S1, determining if at least one first switch of the plurality of switches connected in series along an electrical current path between a power supply terminal and a load terminal is in adverse operating state; and, in a second step, S2, modifying an aspect of the provision of electrical current to the load terminal via the electrical current path on the basis of said determination. Both of steps S1 and S2 may be carried out in accordance with approaches described herein.

The various embodiments described herein are presented only to assist in understanding and teaching the claimed features. These embodiments are provided as a representative sample of embodiments only, and are not exhaustive and/or exclusive. It is to be understood that advantages, embodiments, examples, functions, features, structures, and/or other aspects described herein are not to be considered limitations on the scope of the invention as defined by the claims or limitations on equivalents to the claims, and that other embodiments may be utilised and modifications may be made without departing from the scope of the claimed invention. Various embodiments of the invention may suitably comprise, consist of, or consist essentially of, appropriate combinations of the disclosed elements, components, features, parts, steps, means, etc, other than those specifically described herein. In addition, this disclosure may include other inventions not presently claimed, but which may be claimed in future. The provision system described herein can be implemented as a combustible aerosol provision system, a non-combustible aerosol provision system or an aerosol-free delivery system.

### REFERENCES

[1] Patil N., Celaya J., Das D. Precursor parameter identification for insulated gatebipolar transistor (IGBT) prognostics. IEEE Trans. Reliab. 2009; 58:276-278
[2] Sonnenfeld G., Goebel K., Celaya J.R. An agile accelerated aging, characterization and scenario simulation system for gate controlled power transistors. IEEE Autotestcon. 2008; 6:208-215
[3] Wu LF, Zheng Y, Guan Y, Wang GH, Li XJ., “A non-intrusive method for monitoring the degradation of MOSFETs”, Sensors (Basel). 2014 Jan. 10; 14(1): 1132-9
[4] Celaya, JR., et al. “Towards prognostics of power MOSFETs: Accelerated aging and precursors of failure”, National Aeronautics And Space Administration Moffett Field Ca Ames Research Center, 2010

1. A power control unit, comprising:
at least one power supply terminal for connection to an electrical power supply;
at least one load terminal for connection to an electrical load;
an electrical current path configured to connect the at least one power supply terminal to the at least one load terminal; and
a plurality of switches connected in series along the electrical current path, wherein the power control unit comprises control logic configured to independently switch each of the plurality of switches between an open-circuit state and a closed-circuit state;
wherein the control logic is configured to supply electrical current to the load terminal via the electrical current path; and
wherein the control logic is further configured to determine if at least a first switch of the plurality of switches is in an adverse operating state, and to modify an aspect of the provision of electrical current to the load terminal via the electrical current path on the basis of said determination.

2. The power control unit of claim 1, wherein the determination at least one first switch of the plurality of switches is in an adverse operating state comprises a determination the at least one first switch has failed.

3. The power control unit of claim 2, wherein the determination at least one first switch of the plurality of switches is in an adverse operating state comprises a determination the at least one first switch has failed non-reversibly in a closed-circuit state.

4. The power control unit of claim 1, wherein the determination at least one first switch of the plurality of switches is in an adverse operating state comprises a determination, prior to failure of the at least one first switch, that the at least one first switch has entered a degraded operational condition.

5. The power control unit of claim 2, wherein the modification of the aspect of the provision of electrical current to the load terminal comprises switching at least one second switch of the plurality of switches to an open-circuit state based on determining the at least one first switch has failed.

6. The power control unit of claim 4, wherein the modification of the aspect of the provision of electrical current to the load terminal comprises switching at least one second switch of the plurality of switches to an open-circuit state based on determining the at least one first switch has entered a degraded operational condition.

7. The power control unit of claim 4, wherein the modification of the aspect of the provision of electrical current to the load terminal comprises reducing the electrical power of a supply of electrical current transmitted to the load terminal.

8. The power control unit of claim 1, further operable to receive signals from at least one first switch status sensor configured to detect a first parameter associated with operation of at least one first switch, wherein the power control unit is configured to determine an indication of an operational condition of the at least one first switch on the basis of the received signals, and to determine whether the at least one first switch of the plurality of switches is in an adverse operating state on the basis of the indication of operational condition.

9. The power control unit of claim 8, wherein the first parameter comprises an operating temperature of the at least one first switch, and the received signals are representative of the operating temperature.

10. The power control unit of claim 8, wherein the first parameter comprises an electrical resistance of the at least one first switch, and the received signals are representative of the electrical resistance.

11. The power control unit of claim 8, wherein the first parameter comprises a response time of the at least one first switch to a control signal applied to change the switch state, and the received signals are representative of the response time.

12. The power control unit of claim 8, wherein the power control unit is configured to estimate a remaining lifetime of the at least one first switch, based on the indication of the operational condition of the at least one first switch.

13. The power control unit of claim 12, wherein the estimated lifetime comprises an estimated lifetime until the at least one first switch is in a degraded operational condition.

14. The power control unit of claim 12, wherein the estimated lifetime comprises an estimated lifetime until the at least one first switch fails.

15. The power control unit of claim 12, wherein the estimated remaining lifetime is expressed as a number of opening and closing cycles of the at least one first switch.

16. The power control unit of claim 12, wherein the estimated remaining lifetime is expressed as a duration of current flow through the at least one first switch.

17. The power control unit of claim 12, wherein the estimated remaining lifetime is expressed as an amount of energy transmitted through the at least one first switch.

18. The power control unit of claim 12, wherein the modification of the aspect of the provision of electrical current to the load terminal comprises switching at least one second switch of the plurality of switches to an open-circuit state based on determining a previously estimated remaining lifetime of at least one first switch has elapsed.

19. The power control unit of claim 8, wherein respective ones of the at least one first switch status sensors are individually associated with respective ones of the at least one first switch.

20. The power control unit of claim 8, wherein the at least one first switch comprises a plurality of first switches, and wherein respective ones of the at least one first switch status sensors are individually associated with more than one of the plurality of first switches.

21. The power control unit of claim 8, wherein the at least one first switch comprises a plurality of first switches, and wherein the power control unit is configured to determine a separate indication of the operational condition for each respective one of the plurality of first switches.

22. The power control unit of claim 1, wherein the at least one first switch comprises a plurality of first switches, and wherein the power control unit is configured to separately determine an adverse operating state for each respective one of the plurality of first switches.

23. The power control unit of claim 1, wherein the plurality of switches comprises two switches.

24. The power control unit of claim 1, wherein the plurality of switches comprise solid state switches.

25. The power control unit of claim 24, wherein the plurality of switches comprise field effect transistor, FET, switches.

26. The power control unit of claim 1, wherein the power control unit comprises an application specific integrated circuit, ASIC, package.

27. The power control unit of claim 1, comprising control logic configured to detect a trigger signal provided by an actuation element, and to control the supply of electrical current to the load terminal via the electrical current path on the basis of the trigger signal.

28. The power control unit of claim 27, wherein the actuation element comprises a MEMS airflow sensor.

29. The power control unit of claim 28 when dependent on claim 26, wherein the actuation element is integrated into an ASIC package.

30. The power control unit of claim 29, wherein the ASIC package comprises a single, semiconductor die.

31. An aerosol provision device comprising an electrical power supply, an electrical load comprising an aerosol generator, and the power control unit of claim 1, wherein the at least one power supply terminal is electrically connected to the electrical power supply, and the at least one load terminal is electrically connected to the electrical load.

32. An aerosol provision system comprising the aerosol provision device of claim 31.

33. A method of operating a power control unit to control a supply of power on an electrical current path configured to connect at least one power supply terminal for connection to an electrical power supply to at least one load terminal for connection to an electrical load, via a plurality of switches connected in series along the electrical current path; wherein the method comprises operating control logic comprised in the power control unit, the control logic being configured to supply electrical current to the load terminal via the electrical current path, to cause the control logic to independently switch each of the plurality of switches between an open-circuit state and a closed-circuit state; wherein the method comprises, at the control logic:
determining if at least a first switch of the plurality of switches is in an adverse operating state, and
modifying an aspect of the provision of electrical current to the load terminal via the electrical current path on the basis of said determination.

34. A computer program product comprising instructions to cause a power control unit to execute the steps of the method of claim 33.

35. A computer-readable medium having stored thereon the computer program of claim 34.
